(19) United States
(12) Patent Application Publication
(10) Pub. No.: US 2026/0371769 A1
(43) Pub. Date: Nov. 19, 2026

(54) PHOTOELECTRIC CONVERSION APPARATUS AND RADIATION DETECTION SYSTEM

(71) Applicant: CANON KABUSHIKI KAISHA, Tokyo (JP)

(72) Inventors: TATSUHITO GODEN, Tokyo (JP); ZEMPEI WADA, Saitama (JP); TAKANORI WATANABE, Kanagawa (JP)

(21) Appl. No.: 19/662,071

(22) Filed: Apr. 29, 2026

(30) Foreign Application Priority Data
May 13, 2025 (JP) 2025-080614

(51) Int. Cl. H10F 39/00; H10F 39/18

(52) U.S. Cl. CPC H10F 39/813; H10F 39/8057; H10F 39/811; H10F 39/18

(57) ABSTRACT

A photoelectric conversion apparatus comprising a semiconductor substrate including a pixel region provided with a plurality of pixels so as to form a plurality of rows and a plurality of columns and a peripheral region provided outside the pixel region, is provided. The peripheral region includes a first region and a second region, with the first region being provided between the second region and the pixel region, the first region is provided with a first circuit configured by a transistor including a gate insulating film having a first thickness, the second region is provided with a second circuit configured by a transistor including a gate insulating film having a second thickness, the first thickness is smaller than the second thickness, and the plurality of pixels each include a photoelectric conversion unit configured to generate signal charge corresponding to incident radiation.

### BACKGROUND

### Field of the Technology

The present disclosure relates to a photoelectric conversion apparatus and a radiation detection system.

### Description of the Related Art

There is known a photoelectric conversion apparatus including, on one semiconductor substrate, a pixel region provided with a plurality of pixels and a peripheral region provided with peripheral circuits for driving the pixels. International Publication No. 2013/088634 discloses that a plurality of types of power supply voltages are supplied in accordance with the respective circuits provided in the peripheral region. The gate insulating film of the transistor of a circuit that receives a high power supply voltage is thicker than the gate insulating film of the transistor of a circuit that receives a low power supply voltage.

A photoelectric conversion apparatus is sometimes applied to a radiation detector or used in space. As disclosed in Japanese Patent Laid-Open No. 2009-129958, the thinner the insulating film, the higher the radiation resistance. Radiation resistance needs to be considered for circuit placement in a peripheral region.

### SUMMARY

Some embodiments provide techniques advantageous in improving the radiation resistance.

According to some embodiments, a photoelectric conversion apparatus comprising a semiconductor substrate including a pixel region provided with a plurality of pixels so as to form a plurality of rows and a plurality of columns and a peripheral region provided outside the pixel region, wherein the peripheral region includes a first region and a second region, with the first region being provided between the second region and the pixel region, the first region is provided with a first circuit configured by a transistor including a gate insulating film having a first thickness, the second region is provided with a second circuit configured by a transistor including a gate insulating film having a second thickness, the first thickness is smaller than the second thickness, and the plurality of pixels each include a photoelectric conversion unit configured to generate signal charge corresponding to incident radiation, is provided.

Features of the present disclosure will become apparent from the following description of embodiments with reference to the attached drawings. The following description of embodiments is described by way of example.

### BRIEF DESCRIPTION OF THE DRAWINGS

FIG. 1 is a view showing a configuration example of a photoelectric conversion apparatus according to the present embodiment;

FIG. 2 is a circuit diagram showing an example of a circuit of the photoelectric conversion apparatus according to the present embodiment;

FIG. 3 is a view showing an example of a circuit of the photoelectric conversion apparatus according to the present embodiment;

FIG. 4 is a circuit diagram showing an example of a circuit of the photoelectric conversion apparatus according to the present embodiment;

FIG. 5 is a view showing a configuration example of the photoelectric conversion apparatus according to the present embodiment;

FIG. 6 is a view showing a configuration example of the photoelectric conversion apparatus according to the present embodiment;

FIG. 7 is a view showing a configuration example of a radiation detection system including the photoelectric conversion apparatus according to the present embodiment; and

FIGS. 8A and 8B are schematic views respectively showing configuration examples of equipment and a transmission electron microscope, each serving as a radiation detection system including the photoelectric conversion apparatus according to the present embodiment.

### DESCRIPTION OF THE EMBODIMENTS

Hereinafter, embodiments will be described in detail with reference to the attached drawings. Note, the following embodiments are not intended to limit the scope of the claims. Multiple features are described in the embodiments, but it is not the case that all such features are required, and multiple such features may be combined as appropriate. Furthermore, in the attached drawings, the same reference numerals are given to the same or similar configurations, and redundant description thereof is omitted.

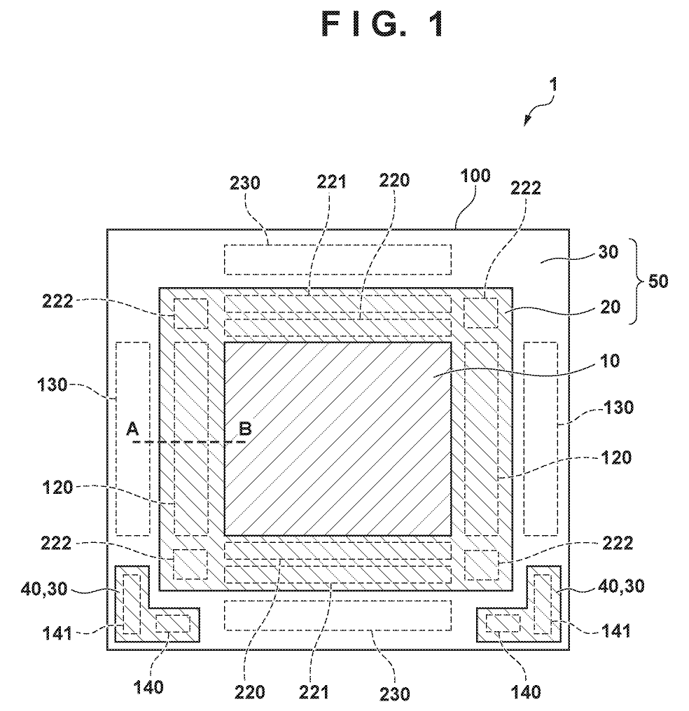

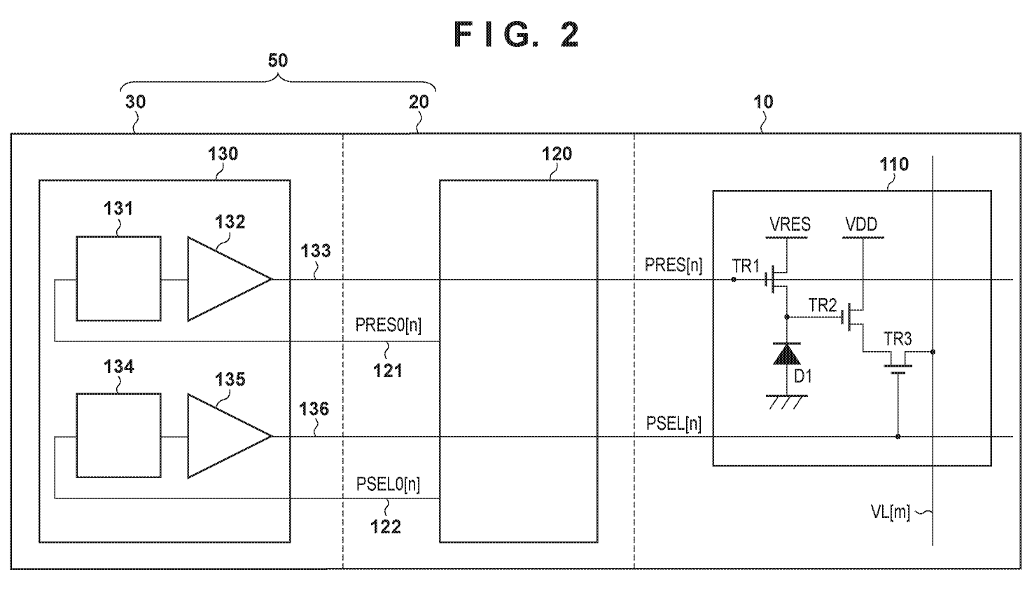

A photoelectric conversion apparatus according to an embodiment of the present disclosure will be described with reference to FIGS. 1-6. FIG. 1 is a schematic view showing a configuration example of a photoelectric conversion apparatus 1 according to the present embodiment. As shown in FIG. 1, the photoelectric conversion apparatus 1 includes a semiconductor substrate 100 including a pixel region 10 provided with a plurality of pixels 110 (shown in FIG. 2) and a peripheral region 50 provided outside the pixel region 10. The peripheral region includes a region 20 and a region 30. The region 20 is provided between the region 30 and the pixel region 10. As shown in FIG. 1, the region 20 may surround the pixel region 10. In addition, the region 30 may surround the region 20. The region 20 is provided adjacent to the pixel region 10. The region 30 is a region between the region 20 and the outer edge of the semiconductor substrate 100. The region 30 can be regarded as a region located farther from the pixel region 10 than the region 20.

In the pixel region 10, a plurality of pixels each including a conversion element for converting light or electromagnetic waves into electric charge and a pixel circuit are arranged so as to form a plurality of rows and a plurality of columns. In the following description, the lateral and vertical directions in the accompanying drawings sometimes respectively indicate the row and column directions.

The region 20 of the peripheral region 50 which is adjacent to the pixel region 10 is provided with circuits including vertical scanning circuits 120, horizontal scanning circuits 220, column memories 221, and a signal processing circuit 222. These circuits are digital circuits. A digital circuit operates at a relatively low voltage of 1.2 V or 1.8 V for high integration and low power consumption.

The region 30 of the peripheral region 50 is provided with circuits including A/D conversion circuits 230 and pixel driving circuits 130. These circuits are analog circuits. An analog circuit allows the selection of a wide operation range for securing a high S/N ratio. Accordingly, the analog circuit operates at a relatively high voltage of 3.3 V or 5 V.

The operating voltage of a circuit provided in the region 20 of the peripheral region 50 is lower than that of a circuit provided in the region 30. In this case, the gate insulating film of the transistor of the circuit provided in the region 20 may be thinner than the gate insulating film of the transistor of the circuit provided in the region 30. For example, the thickness of the gate insulating film of the transistor provided in the region 20 may fall within the range of about 1 nm to 5 nm. In addition, for example, the thickness of the gate insulating film of the transistor provided in the region 30 may fall within the range of about 6 nm to 15 nm.

The region 30 between the region 20 of the peripheral region 50 and the outer edge of the photoelectric conversion apparatus 1 (the semiconductor substrate 100) may include a region 40 provided with a digital circuit. Like the region 20, the region 40 can be provided with a circuit whose operating voltage is lower than that of a circuit provided in the region 30. The region 40 can be provided with, for example, digital circuits such as timing generators (TGs) 140 and output interface circuits 141. Such placement can improve the layout efficiency of a signal wiring pattern and reduce the chip size. This improves the signal quality and suppresses operation failures.

As shown in FIG. 1, the pixel region 10 may have a substantially rectangular shape having sides along the row direction and the column direction along which the pixels 110 are provided. The peripheral region 50 outside the sides of the outer edge of the pixel region 10 which extend along the column direction is provided with the vertical scanning circuits 120 and the pixel driving circuits 130. The plurality of pixels 110 arranged in the pixel region 10 are sequentially selected for each row and driven. The vertical scanning circuit 120 is a signal generating circuit that generates control signals so as to sequentially activate each of selected rows and inactivate unselected rows. The pixel driving circuit 130 is configured to include a level shift circuit and a buffer circuit. The level shift circuit is a circuit that converts the amplitude voltage of the control signal generated by the vertical scanning circuit 120 into an amplitude voltage for driving the pixel 110. The buffer circuit is a circuit for transmitting control signals for controlling the plurality of pixels 110 without causing any distortion and rounding in the signals and is an output circuit for outputting sufficient currents.

In the present embodiment, the pixel region 10 is provided with the pixels 110 in N rows x M columns, where N and M are integers of 1 or more. FIG. 2 is a view for explaining the configurations of the pixel 110, the vertical scanning circuit 120, and the pixel driving circuit 130 in the nth row, where n corresponds to any one of integers from 1 to N. The pixel 110 shown in FIG. 2 includes a conversion element D1, a reset transistor TR1, an amplification transistor TR2, and a selection transistor TR3, but limitation is not made thereto. The pixel 110 may have any appropriate configuration in accordance with the characteristics and the like required for the photoelectric conversion apparatus 1.

The vertical scanning circuit 120 receives the control signals supplied from the TG 140 and the like shown in FIG. 1 and generates control signals PRES0(n) and PSEL0(n). The control signal PRES0(n) is input to the pixel driving circuit 130 via a signal line 121 and is level-converted into a high operating voltage by a level shift circuit 131. The level-converted control signal is output as a reset signal PRES(n) from a buffer circuit 132. The reset signal PRES(n) is input to the pixel 110 via a reset signal line 133, and the reset transistor TR1 of the pixel 110 is driven.

The control signal PSEL0(n) is input to the pixel driving circuit 130 via a signal line 122 and is level-converted by a level shift circuit 134. The level-converted control signal is output as a selection signal PSEL(n) from a buffer circuit 135. The selection signal PSEL(n) is input to the pixel 110 via a selection signal line 136, and the selection transistor TR3 of the pixel 110 is driven.

As shown in FIGS. 1 and 2, the vertical scanning circuit 120 is provided in the region 20 of the peripheral region 50, and the pixel driving circuit 130 is provided in the region 30 of the peripheral region 50. The region 20 is provided between the pixel region 10 and the region 30. Accordingly, the reset signal PRES(n) and the selection signal PSEL(n) output from the pixel driving circuit 130 are respectively supplied to the pixel 110 provided in the pixel region 10 via the reset signal line 133 and the selection signal line 136 provided so as to cross the vertical scanning circuit 120. A conductive pattern to which a fixed potential is supplied may be provided between the vertical scanning circuit 120 and the reset signal line 133 to prevent noise originating from the operation of the vertical scanning circuit 120 from being superimposed on the reset signal PRES(n). Likewise, a conductive pattern to which a fixed potential is supplied may be provided between the vertical scanning circuit 120 and the selection signal line 136 to prevent noise originating from the operation of the vertical scanning circuit 120 from being superimposed on the selection signal PSEL(n).

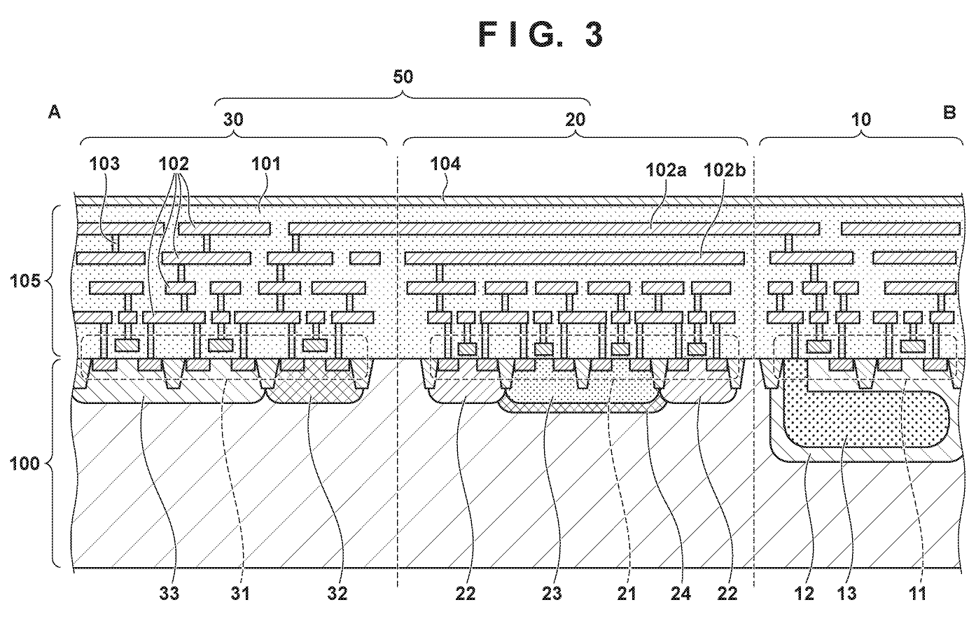

FIG. 3 is a sectional view taken along A - B shown in FIG. 1. FIG. 3 shows a section corresponding to the region 20 provided with the vertical scanning circuit 120, the region 30 provided with the pixel driving circuit 130, and the pixel region 10 shown in FIG. 2.

As shown in FIG. 3, a wiring layer 105 is stacked on the semiconductor substrate 100. As the semiconductor substrate 100, for example, a silicon substrate may be used. The present embodiment exemplifies a case where the semiconductor substrate 100 is an n-type semiconductor. The wiring layer 105 includes a plurality of conductive layers each including a conductive pattern 102 insulated by an interlayer dielectric film 101. The plurality of conductive patterns 102 each are a wiring pattern configuring a signal line or power supply line for controlling, for example, the vertical scanning circuit 120 and the pixel driving circuit 130. The conductive patterns 102, of the conductive patterns 102 provided for different conductive layers which are electrically connected to each other are connected to each other via a conductive plug 103 provided in a via hole provided in the interlayer dielectric film 101 between the conductive layers. The surface of the wiring layer 105 may be provided with a protective film 104. As the protective film 104, an insulator film made of an inorganic insulating material such as silicon oxide, silicon nitride, silicon carbide, or metal oxide may be used.

In the region 20 of the peripheral region 50, a p-type well 22 and an n-type well 23 are formed in the semiconductor substrate 100, and a plurality of transistors 21 constituting the vertical scanning circuit 120 are formed. In the region 30 of the peripheral region 50, a p-type well 32 and an n-type well 33 are formed in the semiconductor substrate 100, and a plurality of transistors 31 constituting the pixel driving circuit 130 are formed. In the pixel region 10, a p-type well 12 is formed in the semiconductor substrate 100, and an n-type semiconductor layer 13 constituting a diode as a conversion element is formed in the p-type well 12. In addition, a plurality of transistors 11 for driving the pixel 110 are formed. As described above, in a case where the semiconductor substrate 100 is of an N type, a p-type semiconductor region 24 is formed under the n-type well 23 in the region 20. This electrically separates the n-type well 23 from the semiconductor substrate 100. This also electrically separates the n-type well 23 from the n-type well 33 and hence can make the operating voltage of the vertical scanning circuit 120 configured by the transistor 21 different from that of the pixel driving circuit 130 configured by the transistor 31. As described above, the operating voltage of the vertical scanning circuit 120 is lower than that of the pixel driving circuit 130, and the gate insulating film of the transistor 21 is thinner than that of the transistor 31. In addition, the p-type well 22 and the n-type well 23 are higher in impurity concentration than the p-type well 32 and the n-type well 33. As a result, the p-type well 22 and the n-type well 23 are lower in resistivity than the p-type well 32 and the n-type well 33.

A conductive pattern 102a shown in FIG. 3 is part of the reset signal line 133 in FIG. 2. A conductive pattern 102b is provided on the lower layer (between the conductive pattern 102a and the semiconductor substrate 100) of the conductive pattern 102a. A predetermined potential (fixed potential) is supplied to the conductive pattern 102b to prevent noise originating from the operation of the transistor 21 from being superimposed on the reset signal PRES(n).

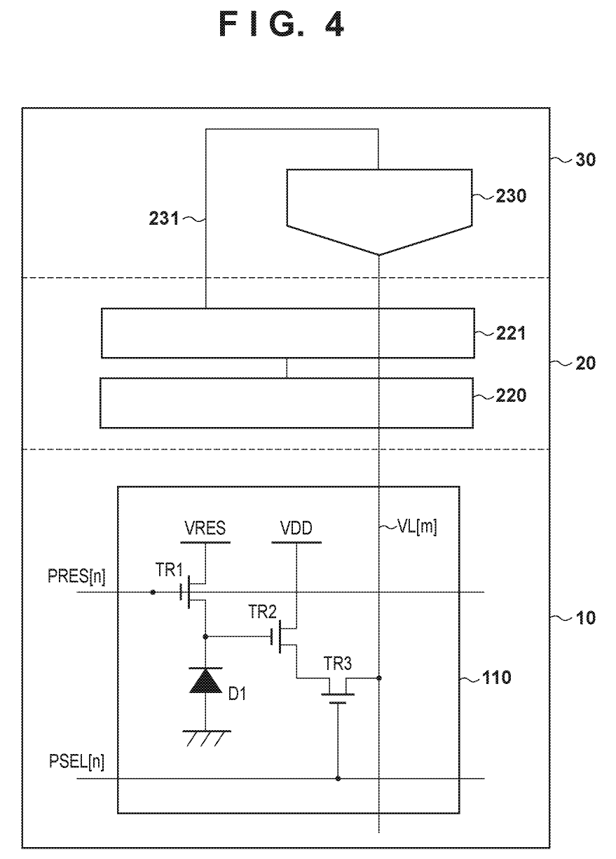

The peripheral region 50 outside a side of the outer edge of the pixel region 10 which extends along the row direction is provided with the horizontal scanning circuit 220, the column memory 221, and the A/D conversion circuit 230. FIG. 4 is a circuit diagram for explaining the configurations of the pixel 110, the horizontal scanning circuit 220, the column memory 221, and the A/D conversion circuit 230 in the mth column, where m corresponds to any one of integers from 1 to M.

The pixel signal output from the pixel 110 in the row selected by the vertical scanning circuit 120 is input to the A/D conversion circuit 230 via a vertical signal line VL(m). The pixel signal is A/D-converted by the A/D conversion circuit 230 and output as a digital signal to a signal line 231. The digital signal output to the signal line 231 is held in the column memory 221. A selection signal is output from the horizontal scanning circuit 220, and a digital signal is read out from the selected column memory 221. The digital signal read out from the column memory 221 is input to the signal processing circuit 222 shown in FIG. 1 and subjected to signal processing.

As the A/D conversion circuit 230, a ramp-type A/D conversion circuit constituted by a ramp generating circuit, a comparator, and a counter, a delta-sigma A/D conversion circuit, a pipeline A/D conversion circuit, or the like can be used. An appropriate conversion circuit may be selected from these conversion circuits in accordance with the characteristics required for the photoelectric conversion apparatus 1.

As shown in FIG. 4, the horizontal scanning circuit 220 and the column memory 221 are provided in the region 20 of the peripheral region 50, and the A/D conversion circuit 230 is provided in the region 30 of the peripheral region 50. The region 20 is provided between the pixel region 10 and the region 30. Accordingly, the pixel signal output from the pixel 110 is supplied to the A/D conversion circuit 230 via the vertical signal line VL(m) provided so as to cross the horizontal scanning circuit 220 and the column memory 221. In order to prevent noise originating from the operations of the horizontal scanning circuit 220 and the column memory 221 from being superimposed on a pixel signal, a conductive pattern to which a fixed potential is supplied may be provided between the horizontal scanning circuit 220 and the vertical signal line VL(m) and between the column memory 221 and the vertical signal line VL(m).

The influence of radiation on a transistor will be described next. The photoelectric conversion apparatus 1 is sometimes applied to a radiation detector and incorporated in a radiation detection system. In the following description, "radiation" is a concept including electromagnetic radiation (X-rays, gamma rays, and the like), particle radiation (electron rays, proton rays, neutron rays, alpha rays, and the like), and non-ionizing radiation (radio waves, microwaves, infrared rays, visible rays, and the like). The term "radiation detection system" indicates a system in general which is configured to acquire an image of an imaging target (an object, a patient in a case of a medical imaging system, or the like) as electronic data by using radiation. The term "image" indicates a still image or moving image. In addition, for example, the photoelectric conversion apparatus 1 may be used in space. In such a case, the electric charge or defect in the gate insulating film of a transistor is increased by irradiation with radiation. An increase in electric charge or defect in the gate insulating film may affect the operation of the transistor and cause an operation failure in the circuit. The occurrence of an operation failure makes it impossible to normally detect electromagnetic waves such as radiation or visible light, thus leading to a deterioration in image quality obtained by the photoelectric conversion apparatus 1 or failure. The present inventors have confirmed that thinning the gate insulating film has reduced the influence due to an increase in electric charge or defect in the gate insulating film and can suppress operation failures.

In a case where the photoelectric conversion apparatus 1 is applied to a radiation detector, a shielding member having an opening portion so as to shield the peripheral region 50 and irradiate the pixel region 10 with radiation is sometimes attached to the photoelectric conversion apparatus 1. In addition, the housing of an imaging apparatus such as a camera incorporating the photoelectric conversion apparatus 1 sometimes functions as a shielding member for shielding the peripheral region 50. With this configuration, although the shielding member shields the peripheral region 50 so as to make it less likely that the peripheral region 50 will be irradiated with radiation, the radiation applied from the opening portion to the pixel region 10 is scattered and comes around to the peripheral region 50. This may cause the radiation to reach the region 20 of the peripheral region 50.

In the photoelectric conversion apparatus 1 according to the present embodiment, the region 20 of the peripheral region 50 which is adjacent to the pixel region 10 is provided with a transistor having a gate insulating film thinner than that of a transistor provided in the region 30. A transistor having a thin gate insulating film is higher in radiation resistance than a transistor having a thick gate insulating film. Accordingly, even if the radiation incident on the pixel region 10 is scattered and has reached the region 20, it is possible to suppress operation failures in the circuit provided in the region 20. If the gate insulating film of the transistor provided in the region 20 has, for example, a thickness of 5 nm or less, it is possible to obtain satisfactorily high radiation resistance.

Even in the case where the photoelectric conversion apparatus 1 is used in space, radiation (cosmic radiation) with high energy can enter the photoelectric conversion apparatus 1. The peripheral region 50 can be shielded by the shielding member or the housing so as to make it difficult to irradiate the peripheral region 50 with radiation. However, heavy particle beams and the like may come around to the peripheral region 50 from the opening portion provided at a position corresponding to the pixel region 10, and hence may result in an operation failure in the circuit provided in the region 20.

In the photoelectric conversion apparatus 1 according to the present embodiment, the operating voltage of the region 20 of the peripheral region 50 which is adjacent to the pixel region 10 is lower than that of the region 30. A transistor constituting a circuit with a low operating voltage is formed on the assumption of a high-speed operation and has a well whose impurity concentration is high to increase the driving performance. Accordingly, the well has a low resistivity. This suppresses noise because it reduces a change in the potential of the well due to the electric charge generated at the time of incidence of heavy particle beams or the like, thereby suppressing operation failures in the circuit. A circuit with, for example, an operating voltage of 2 V or less as the operating voltage of the region 20 can obtain a satisfactory noise suppression effect. That is, high radiation resistance can be obtained.

As described above, a digital circuit is provided in the region 20 of the peripheral region 50, and an analog circuit is provided in the region 30 between the region 20 and the outer edge of the semiconductor substrate 100. The digital circuit having a thinner gate insulating film and lower operating voltage than the analog circuit is provided adjacent to the pixel region 10. This can implement a circuit placement that improves the radiation resistance and has a high layout efficiency.

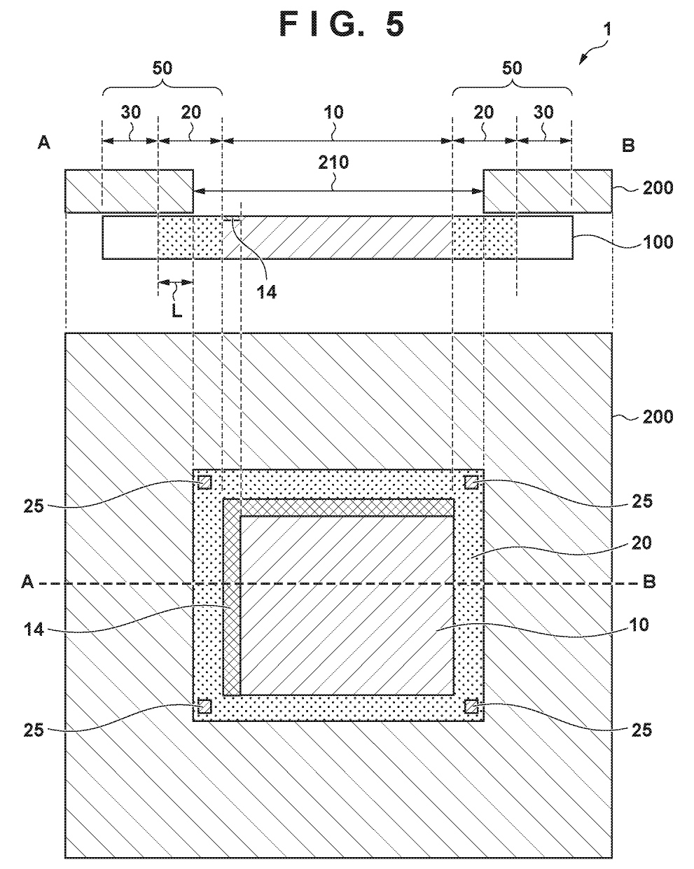

FIG. 5 is a view showing a configuration provided with a shielding member 200 for the use of the photoelectric conversion apparatus 1 as a radiation detector. The upper side of FIG. 5 is a sectional view of the photoelectric conversion apparatus 1. The lower side of FIG. 5 is a plan view when the photoelectric conversion apparatus 1 is seen from the upper surface side in planar view. A sectional view of the upper side of FIG. 5 shows a section taken along A - B in the plan view of the lower side.

As shown in FIG. 5, the photoelectric conversion apparatus 1 is provided with an opening portion 210 at a position corresponding to the pixel region 10 and the shielding member 200 is provided so as to cover the region 30 of the peripheral region 50. The shielding member 200 is provided on a side of the surface of the semiconductor substrate 100 which radiation enters. The region 30 of the peripheral region 50 is covered by the shielding member 200 so as to shield against radiation. This prevents the occurrence of electric charges and defects in the region 30 due to radiation and hence suppresses operation failures in the circuit provided in the region 30.

In addition, as shown in FIG. 5, in planar view, the outer edge of the opening portion 210 provided in the shielding member 200 can be provided at a position to overlap the region 20 of the peripheral region 50. Such placement makes the region 30 be reliably covered by the shielding member 200. On the other hand, part of the region 20 is irradiated with radiation without being shielded. However, the gate insulating film of the transistor provided in the region 20 is thin and high in radiation resistance, thereby suppressing operation failures in the circuit.

The size of the region 20 provided with the circuit constituted by the transistor having the thin gate insulating film is determined in consideration of variation in the positioning of the shielding member 200 and the spread of radiation coming around to the region 30 from the opening portion 210. In consideration of the scattering of radiation in the semiconductor substrate 100, a distance L from an end portion of the opening portion 210 provided in the shielding member 200 to the region 30 may be, for example, 200 μm or more.

In order to provide the shielding member 200 in the photoelectric conversion apparatus 1, the semiconductor substrate 100 is aligned with the shielding member 200 with reference to alignment marks 25 placed in the region 20 of the peripheral region 50. In accordance with the rectangular pixel region 10, the opening portion 210 provided in the shielding member 200 may have a rectangular shape and may be provided with the alignment marks 25 at positions corresponding to the four corners of the opening portion 210 of the semiconductor substrate 100 in planar view. The shape of the alignment mark 25 generally has a cross pattern, L-shaped pattern, or the like, but limitation is not made thereto. The alignment mark 25 may have another shape.

In addition, the outer edge of the pixel region 10 may be provided with an optical black (OB) pixel covered by a light-shielding film 14. Using the difference between a signal from a normal pixel and a pixel from the OB pixel makes it possible to perform correction processing of removing a dark current component. The region provided with the OB pixel for the signal correction of the pixels arranged two-dimensionally may be provided along two sides of the outer edge portion of the pixel region 10 which are orthogonal to each other.

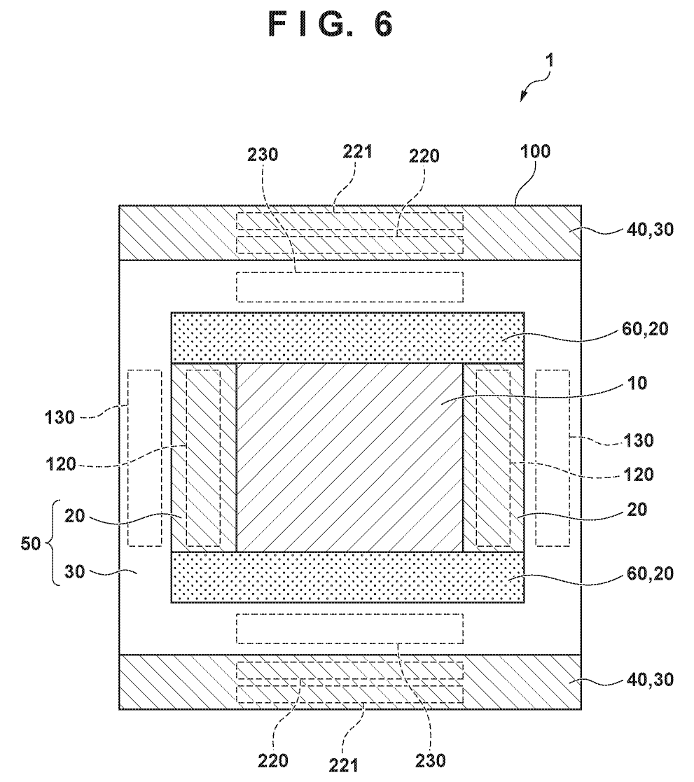

FIG. 6 is a view showing a modification of the photoelectric conversion apparatus 1 described above. In the configuration shown in FIG. 1, the circuits provided in the region 20 of the peripheral region 50 are provided along two sides of the outer edge of the pixel region 10 which extend along the row direction and two sides of the outer edge of the pixel region 10 which extend along the column direction. In contrast to this, in the configuration shown in FIG. 6, the circuits provided in the region 20 of the peripheral region 50 are provided along one of a) the two sides of the outer edge of the pixel region 10 which extend along the row direction and b) the two sides of the outer edge of the pixel region 10 which extend along the column direction. Regions of the region 20 which extend along the other of a) the two sides along the row direction and b) the two sides along the column direction are buffer regions 60 not provided with any circuit including a transistor. In the configuration shown in FIG. 6, regions of the region 20 which are provided with circuits including transistors can also be regarded as regions adjacent to two opposing sides of the pixel region 10.

FIG. 6 shows an example in which the peripheral region 50 outside the sides of the outer edge of the pixel region 10 in the column direction has the vertical scanning circuit 120 provided in the region 20 and the pixel driving circuit 130 is provided in the region 30. Similar to the configuration shown in FIG. 1, the pixel driving circuits 130 are provided between the vertical scanning circuits 120 and the outer edge of the semiconductor substrate 100.

For example, in the peripheral region 50 outside the sides of the outer edge of the pixel region 10 which extend in the row direction, the buffer regions 60 are provided adjacent to the pixel region 10 as the regions 20, and each region 30 is provided with the A/D conversion circuit 230, the horizontal scanning circuit 220, and the column memory 221. As described above, each region 30 may include the region 40 provided with digital circuits. The horizontal scanning circuit 220 and the column memory 221 are provided in the region 40. In the configuration shown in FIG. 6, a region of the region 30 which is provided with the A/D conversion circuit 230 is located between the region 20 (the buffer region 60) and the outer edge of the semiconductor substrate 100. In addition, the region 40 of the region 30 which is provided with a digital circuit is located between the region provided with the A/D conversion circuit 230 and the outer edge of the semiconductor substrate 100. It can also be regarded that the A/D conversion circuit 230 is provided between the buffer region 60 and the outer edge of the semiconductor substrate 100, and the horizontal scanning circuit 220 and the column memory 221 are provided between the A/D conversion circuit 230 and the outer edge of the semiconductor substrate 100.

In the placement configuration shown in FIG. 6, the pixel signal output from the pixel region 10 is input to the A/D conversion circuit 230 as an analog circuit without crossing the horizontal scanning circuit 220 and the column memory 221 which are digital circuits. Accordingly, noise originating from the operations of the horizontal scanning circuit 220 and the column memory 221 is not superimposed on the pixel signal, and hence the signal quality can be kept high.

In the present embodiment, the vertical scanning circuits 120 are provided adjacent to two opposing sides of the pixel region 10 of the region 20. The region 20 is provided with a transistor having a thinner gate insulating film than a transistor included in an analog circuit provided in the region 30 and has high radiation resistance as described above. Accordingly, it is possible to obtain effects similar to those described above.

The buffer region 60 is provided adjacent to the pixel region 10. The buffer region 60 is provided with conductive patterns such as a power supply wiring pattern, a signal wiring pattern, and dummy wiring pattern without being provided with semiconductor elements such as transistors constituting a control circuit, a signal processing circuit, and the like. Predetermined potentials corresponding to the respective conductive patterns are supplied to the conductive patterns so as to prevent the conductive patterns from becoming electrically floating. Supplying a potential to a conductive pattern will discharge the charge generated by irradiation with radiation from the conductive pattern, thereby preventing the insulating layer from being broken down by charge-up. Accordingly, even in a case where the buffer region 60 is irradiated with radiation, no breakdown or the like occurs in the insulating layer. Even in a case where radiation is scattered outside the pixel region 10, providing the buffer region 60 (the region 20) will prevent the radiation from reaching the circuit provided in the region 30. This makes it possible to suppress operation failures in the circuits provided in the peripheral region 50.

Even in the configuration shown in FIG. 6, the photoelectric conversion apparatus 1 may include the shielding member 200 as shown in FIG. 5. In planar view, the outer edge of the opening portion 210 provided in the shielding member 200 is provided at a position to overlap the region 20 (the region provided with the circuits and the buffer region 60 provided with no circuits). With this placement, the region 30 is reliably covered by the shielding member 200. Part of the region 20 is not shielded and is irradiated with radiation. However, the gate insulating film of the transistor provided in the region 20 is thin and high in radiation resistance, thus suppressing operation failures in the circuit. In addition, since a potential is supplied to the conductive pattern provided in the buffer region 60, the possibility of breakdown in the buffer region 60 is low.

The configuration shown in FIG. 6 is provided with circuits adjacent to one set of two opposing sides of the four sides of the outer edge of the pixel region 10 of the region 20 and is provided with the buffer regions 60 adjacent to the other set of two sides. However, limitation is not made thereto. For example, circuits may be provided adjacent to three sides of the four sides of the outer edge of the pixel region 10 of the region 20, and the buffer region 60 may be provided adjacent to the remaining one side. In addition, for example, the buffer regions 60 may be provided adjacent to three sides of the four sides of the outer edge of the pixel region 10 of the region 20, and a circuit may be provided adjacent to the remaining one side. Furthermore, the configuration shown in FIG. 6 is provided with the circuits (the vertical scanning circuits 120) adjacent to two sides of the outer edge of the pixel region 10 which extend along the column direction but may be provided with the circuits (the vertical scanning circuits 120) adjacent to the two sides along the row direction. In this case, the buffer regions 60 are provided adjacent to the two sides of the outer edge of the pixel region 10 which extend along the column direction.

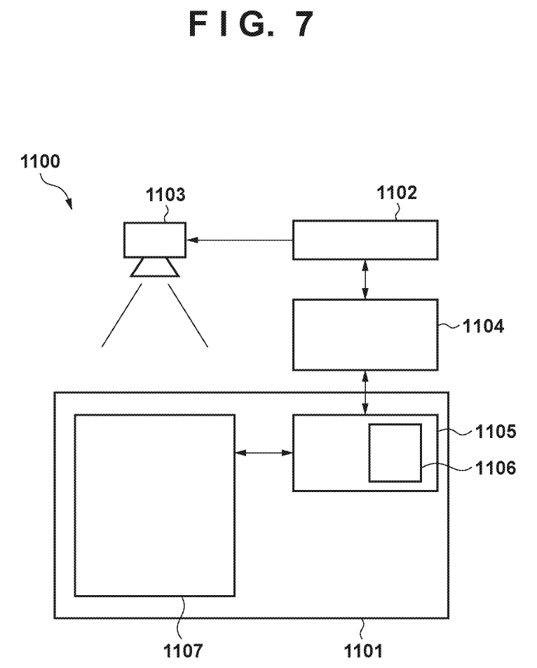

An example of application to, for example, the radiation detector of the above photoelectric conversion apparatus 1 will be described next. FIG. 7 is a view showing a configuration example of a radiation detection system 1100 incorporating the photoelectric conversion apparatus 1. The radiation detection system 1100 can include a radiation detector 1101, an exposure controller 1102, a radiation source 1103 that irradiates the radiation detector 1101 with radiation, and a computer 1104. The radiation detector 1101 includes an imaging unit 1107 including a plurality of pixels. As the imaging unit 1107, the photoelectric conversion apparatus 1 described above can be used. An appropriate photodiode may be used for a conversion element D1 used for the pixel 110 of the photoelectric conversion apparatus 1 in accordance with the type of radiation to be applied. Alternately, a wavelength conversion material such as a scintillator may be used for the conversion element D1 in addition to the photodiode. This makes each of the plurality of pixels 110 include a photoelectric conversion unit that generates signal charge corresponding to incident radiation.

The radiation source 1103 starts irradiation with radiation in accordance with an exposure command supplied from the exposure controller 1102. The radiation emitted from the radiation source 1103 enters the imaging unit 1107 of the radiation detector 1101 through an imaging target. The radiation source 1103 stops the irradiation with radiation in accordance with a stop command from the exposure controller 1102.

The radiation detector 1101 can be a flat panel detector used for, for example, radiation imaging in medical image diagnosis or non-destructive inspection. The imaging unit 1107 of the radiation detector 1101 can have a plate-like shape with a size matching the size of an imaging target. For example, the imaging unit 1107 is provided with 3300 x 2800 pixels on a 550 mm x 445 mm substrate. The radiation detector 1101 may have a direct conversion type configuration that converts radiation into signal charge with a diode provided in the pixel array of the imaging unit 1107.

The radiation detector 1101 can include the imaging unit 1107, a controller 1105 for controlling the imaging unit 1107, and a signal processing unit 1106 for processing the signal output from the imaging unit 1107. For example, the signal processing unit 1106 may process the signal output from the imaging unit 1107 and output the processed signal as digital image data to the computer 1104. In addition, the signal processing unit 1106 may generate a stop signal for stopping irradiation with radiation from the radiation source 1103 based on the signal output from the imaging unit 1107. The stop signal is supplied to the exposure controller 1102 via the computer 1104. The exposure controller 1102 then sends a stop command to the radiation source 1103 in response to the stop signal.

The controller 1105 may be, for example, a programmable logic device (PLD) such as a field programmable gate array (FPGA) or an application specific integrated circuit (ASIC). Alternatively, the controller 1105 may be a general-purpose computer incorporating programs. Alternatively, the controller 1105 may be a combination of all or some of these components.

The present embodiment has exemplified that the signal processing unit 1106 is provided in the controller 1105 or serves as part of the function of the controller 1105, but limitation is not made thereto. The controller 1105 and the signal processing unit 1106 may have different configurations. In addition, the signal processing unit 1106 may be provided independently of the radiation detector 1101. For example, the computer 1104 may have the same function as that of the signal processing unit 1106. Accordingly, the signal processing unit 1106 can be included in the radiation detection system 1100 as a signal processing apparatus that processes the signal output from the radiation detector 1101.

The computer 1104 can control the radiation detector 1101 and the exposure controller 1102 and perform the processing for receiving radiation image data from the radiation detector 1101 and displaying the received data as a radiation image. The computer 1104 can function as an input unit for allowing the user to input conditions for imaging to obtain radiation images.

For example, the exposure controller 1102 has an exposure switch. When the user turns on the exposure switch, the exposure controller 1102 sends an exposure command to the radiation source 1103 and also sends a start notification indicating the start of irradiation with radiation to the computer 1104. Upon receiving the start notification, the computer 1104 notifies the controller 1105 of the radiation detector 1101 of the start of irradiation with radiation in response to the start notification. In accordance with this operation, the controller 1105 causes the imaging unit 1107 to generate a signal corresponding to the incident radiation.

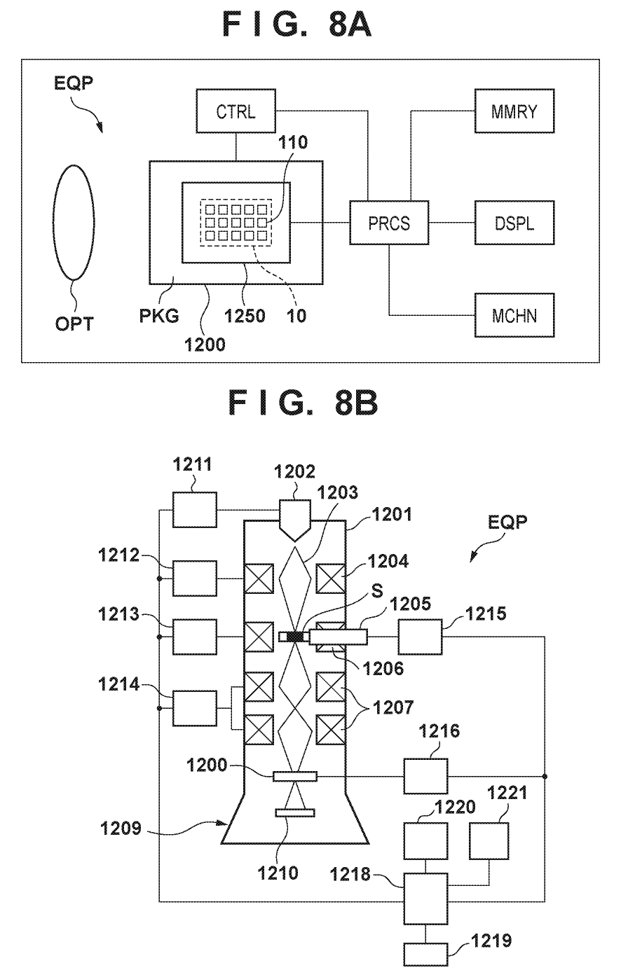

Another example of the radiation detection system incorporating the photoelectric conversion apparatus 1 will be described next with reference to FIGS. 8A and 8B.

FIG. 8A shows equipment EQP as a radiation detection system including a radiation detector 1200 including the photoelectric conversion apparatus 1 described above. The radiation detector 1200 includes an imaging unit 1250 and a package PKG for mounting the imaging unit 1250. As the imaging unit 1250, the above photoelectric conversion apparatus 1 can be used.

The equipment EQP can further include at least one of an optical system OPT, a control device CTRL, a processing device PRCS, a display device DSPL, a storage device MMRY, and a mechanical device MCHN. The optical system OPT forms an image of radiation on the radiation detector 1200, and is, for example, a lens, a shutter, and a mirror. The optical system OPT may form an image of a particle beam such as an electron beam or a proton beam on the radiation detector 1200 in accordance with the kind of radiation to be handled. The control device CTRL controls the radiation detector 1200, and is, for example, an ASIC. The processing device PRCS processes a signal output from the radiation detector 1200, and is, for example, a device such as a CPU or an ASIC for forming an Analog Front End (AFE) or a Digital Front End (DFE). The display device DSPL is an EL display device or a liquid crystal display device that displays, in a format such as a visible image, information obtained by the radiation detector 1200. The storage device MMRY is a magnetic device or a semiconductor device for storing information obtained by the radiation detector 1200. The storage device MMRY is a volatile memory such as an SRAM or a DRAM or a nonvolatile memory such as a flash memory or a hard disk drive. The mechanical device MCHN includes a moving or propulsion unit such as a motor or an engine.

In the equipment EQP, a signal output from the radiation detector 1200 is displayed on the display device DSPL, or transmitted to an external device by a communication device (not shown) included in the equipment EQP. Hence, the equipment EQP may further include the storage device MMRY and the processing device PRCS in addition to a storage circuit and an arithmetic circuit included in the radiation detector 1200. The mechanical device MCHN may be controlled based on the signal output from the radiation detector 1200.

The equipment EQP shown in FIG. 8A may be medical equipment such as an endoscope or radiation diagnostic equipment, measurement equipment such as a distance measurement sensor, or analysis equipment such as an electron microscope.

FIG. 8B is a schematic view showing the configuration of a Transmission Electron Microscope (TEM) as an example of the equipment EQP. The equipment EQP serving as an electron microscope includes an electron beam source 1202 (electron gun) as an irradiation unit of radiation (electron beams), an irradiation lens 1204, a vacuum chamber 1201 (lens barrel), an object lens 1206, and a magnifying lens system 1207. The equipment EQP also includes a camera 1209 as an imaging unit. The camera 1209 includes the radiation detector 1200 including the photoelectric conversion apparatus 1 described above.

An electron beam 1203 as an energy beam emitted from the electron beam source 1202 is focused by the irradiation lens 1204, and irradiates a sample S as an analysis target held by a sample holder. A space through which the electron beam 1203 passes is formed by the vacuum chamber 1201 (lens barrel), and is held in vacuum. The radiation detector 1200 is arranged to face the vacuum space through which the electron beam 1203 passes. The electron beam 1203 transmitted through the sample S is magnified by the object lens 1206 and the magnifying lens system 1207, and projected to the radiation detector 1200. An electron optical system for irradiating the sample S with an electron beam is called an irradiation optical system, and an electron optical system for forming an image of the electron beam transmitted through the sample S on the radiation detector 1200 is called an imaging optical system.

The electron beam source 1202 is controlled by an electron beam source control device 1211. The irradiation lens 1204 is controlled by an irradiation lens control device 1212. The object lens 1206 is controlled by an object lens control device 1213. The magnifying lens system 1207 is controlled by a magnifying lens system control device 1214. A control mechanism 1205 of the sample holder is controlled by a holder control device 1215 configured to control a driving mechanism of the sample holder.

The electron beam 1203 transmitted through the sample S is detected by a direct electron detector 1200 of the camera 1209. A signal output from the direct electron detector 1200 is processed by a signal processing device 1216 and an image processing device 1218 serving as the processing device PRCS, thereby generating an image signal. The generated image signal (transmission electron image) is displayed on an image display monitor 1220 and an analysis monitor 1221 corresponding to the display device DSPL.

The camera 1209 is provided in the lower portion of the equipment EQP. The camera 1209 includes the radiation detector 1200 that directly converts an electron beam into a charge signal. At least part of the camera 1209 is provided in the camera 1209 so as to be exposed to the vacuum space formed by the vacuum chamber 1201. The electron beam 1203 transmitted through the radiation detector 1200 is absorbed by an electron beam absorbing member 1210. The camera 1209 can also be attached to and detached from the vacuum chamber 1201. In a case where the radiation detector 1200 needs to be replaced, the camera 1209 can be detached from the vacuum chamber 1201 and replaced with a new camera. An openable/closable vacuum partition may be provided between the camera 1209 and the vacuum chamber 1201 to replace the camera 1209 without breaking the vacuum of the vacuum chamber 1201.

Each of the electron beam source control device 1211, the irradiation lens control device 1212, the object lens control device 1213, the magnifying lens system control device 1214, and the holder control device 1215 is connected to the image processing device 1218. This allows them to exchange data in order to set the imaging condition of the electron microscope. In this case, the electron beam source control device 1211 and the image processing device 1218 function as a control means for controlling an irradiation rate. By a signal supplied from the image processing device 1218, driving control of the sample holder and setting of the observation condition of each lens can be performed.

An operator prepares the sample S as an imaging target, and sets imaging conditions using an input device 1219 connected to the image processing device 1218. Predetermined data is input to each of the electron beam source control device 1211, the irradiation lens control device 1212, the object lens control device 1213, and the magnifying lens system control device 1214 to obtain a desired acceleration voltage, magnification, and observation mode. Furthermore, the operator inputs conditions such as the number of continuous visual field images, an imaging start position, and the moving speed of the sample holder to the image processing device 1218 using the input device 1219 such as a mouse, a keyboard, and a touch panel. The image processing device 1218 may automatically set the conditions regardless of the operator input.

The radiation detector and the radiation detection system described above are merely exemplary, and the photoelectric conversion apparatus 1 described above may be applied to another apparatus or system.

According to the present disclosure, it is possible to provide a technique advantageous in improving the radiation resistance.

While the present disclosure has been described with reference to embodiments, it is to be understood that the present disclosure is not limited to the disclosed embodiments. The scope of the following claims is to be accorded the broadest interpretation so as to encompass all such modifications and equivalent structures and functions.

This application claims the benefit of Japanese Patent Application No. 2025-080614, filed May 13, 2025, which is hereby incorporated by reference herein in its entirety.

What is claimed is:

1. A photoelectric conversion apparatus comprising a semiconductor substrate including a pixel region provided with a plurality of pixels so as to form a plurality of rows and a plurality of columns and a peripheral region provided outside the pixel region,
wherein the peripheral region includes a first region and a second region, with the first region being provided between the second region and the pixel region,
the first region is provided with a first circuit configured by a transistor including a gate insulating film having a first thickness,
the second region is provided with a second circuit configured by a transistor including a gate insulating film having a second thickness,
the first thickness is smaller than the second thickness, and
the plurality of pixels each include a photoelectric conversion unit configured to generate signal charge corresponding to incident radiation.

2. The apparatus according to claim 1, further comprising a shielding member provided with an opening portion at a position corresponding to the pixel region and provided so as to cover the second region.

3. The apparatus according to claim 2, wherein an outer edge of the opening portion is provided at a position to overlap the first region in planar view.

4. The apparatus according to claim 1, wherein the first circuit includes a digital circuit, and
the second circuit includes an analog circuit.

5. The apparatus according to claim 1, wherein the first circuit includes portions provided along two sides of the outer edge of the pixel region which extend along a row direction and two sides of the outer edge of the pixel region which extend along a column direction.

6. The apparatus according to claim 1, wherein the first circuit includes portions are provided along one of two sides of the outer edge of the pixel region which extend along in a row direction and two sides of the outer edge of the pixel region which extend along a column direction.

7. The apparatus according to claim 6, wherein a third regions of the first region which extend along the other of two sides of the first region which extend along the row direction and two sides of the first region which extend along the column direction are not provided with circuits including transistors.

8. The apparatus according to claim 7, wherein the third region is provided with a conductive pattern to which a predetermined potential is supplied.

9. A photoelectric conversion apparatus comprising a semiconductor substrate including a pixel region provided with a plurality of pixels so as to form a plurality of rows and a plurality of columns and a peripheral region provided outside the pixel region,
wherein the peripheral region includes a first region and a second region, with the first region being provided between the second region and the pixel region,
the first region is provided with a first circuit configured to operate at a first voltage,
the second region is provided with a second circuit configured to operate at a second voltage, and
the first voltage is lower than the second voltage.

10. The apparatus according to claim 9, further comprising a shielding member provided with an opening portion at a position corresponding to the pixel region and provided so as to cover the second region.

11. The apparatus according to claim 10, wherein an outer edge of the opening portion is provided at a position to overlap the first region in planar view.

12. The apparatus according to claim 9, wherein the first circuit includes a digital circuit, and
the second circuit includes an analog circuit.

13. The apparatus according to claim 9, wherein the first circuit includes portions provided along two sides of the outer edge of the pixel region which extend along a row direction and two sides of the outer edge of the pixel region which extend along a column direction.

14. The apparatus according to claim 9, wherein the first circuit includes portions provided along one of two sides of the outer edge of the pixel region which extend along in a row direction and two sides of the outer edge of the pixel region which extend along a column direction.

15. The apparatus according to claim 14, wherein a third regions of the first region which extend along the other of two sides of the first region which extend along the row direction and two sides of the first region which extend along the column direction are not provided with circuits including transistors.

16. The apparatus according to claim 15, wherein the third region is provided with a conductive pattern to which a predetermined potential is supplied.

17. The apparatus according to claim 9, wherein a resistivity of a well of the semiconductor substrate which is provided with the first circuit is lower than a resistivity of a well of the semiconductor substrate which is provided with the second circuit.

18. The apparatus according to claim 9, wherein the plurality of pixels each include a photoelectric conversion unit configured to generate signal charge corresponding to incident radiation.

19. A photoelectric conversion apparatus comprising a semiconductor substrate including a pixel region provided with a plurality of pixels so as to form a plurality of rows and a plurality of columns and a peripheral region provided outside the pixel region,
wherein the peripheral region includes a first region and a second region, with the first region being provided between the second region and the pixel region,
the first region is provided with a first circuit configured by a transistor including a gate insulating film having a first thickness,
the second region is provided with a second circuit configured by a transistor including a gate insulating film having a second thickness,
the first thickness is smaller than the second thickness,
the apparatus further comprises a shielding member provided with an opening portion at a position corresponding to the pixel region and provided so as to cover the second region, and
an outer edge of the opening portion is provided at a position to overlap the first region in planar view.

20. A radiation detection system comprising:
the photoelectric conversion apparatus according to claim 1; and
a radiation source configured to irradiate the photoelectric conversion apparatus with radiation.
